(19) United States
(12) Patent Application Publication
(10) Pub. No.: US 2006/0067115 A1
(43) Pub. Date: Mar. 30, 2006

(54) MRAM with improved storage and read out characteristics

(75) Inventors: Arndt Gruber, Munchen (DE); Evangelos Stavrou, Spata (GR); Bachmann Bjorn, Muelsen (DE)

Correspondence Address: MORRISON & FOERSTER LLP, 1650 TYSONS BOULEVARD, SUITE 300, MCLEAN, VA, 22102, US

(73) Assignee: INFINEON TECHNOLOGIES AG, Munchen (DE)

(21) Appl. No.: 11/207,197

(22) Filed: Aug. 19, 2005

(30) Foreign Application Priority Data
Sep. 1, 2004 (DE) 10 2004 042 338.5

(51) Int. Cl. G11C 11/14

(52) U.S. Cl. 365/171

(57) ABSTRACT

The object of designing a magneto resistive memory such that it is as resistant as possible to magnetic stray fields, offers a longest possible retention time of the information stored, and ensures a good read signal, which is achieved by the MRAM memory cells comprising a first ferromagnetic layer or reference layer, a second ferromagnetic layer or reference layer adapted to be magnetized by an external magnetic field, and a non-magnetic or non-magnetizable intermediate layer positioned between the first and second ferromagnetic layers, wherein a ferrimagnetic assistant layer is at least partially adjacently positioned at the ferromagnetic memory layer of the MRAM memory cells, and is adapted to be mechanically coupled therewith. The present invention offers higher stability and longer retention of the information stored, and thus an improvement of the read out signal.

The invention relates to a magneto resistive memory device (MRAM) according to the preamble of claim 1. In particular, the invention relates to a magneto resistive MRAM memory (Magnetic Random Access Memory) of the optional access type, comprising a plurality of MRAM memory cells with a first ferromagnetic layer or reference layer, respectively, and a second ferromagnetic layer or magnetizable storage layer, respectively, that is adapted to be magnetized by an external magnetic field, and a non-magnetizable intermediate layer positioned between the first and second ferromagnetic layers, wherein the memory cells each are formed at the crosspoints of a cell field composed of a matrix of column and row supply lines and are connected to the supply lines for transmitting read and write currents, wherein, during a write operation, the magnetic fields generated by the write currents in the respective supply lines add up in an optional crosspoint and thus enable a magnetization or a re-magnetization, respectively, of the corresponding memory cell. The invention further relates to the use of such a memory for performing write and read operations.

In the case of conventional semiconductor memory devices one differentiates between so-called functional memory devices (e.g. PLAs, PALs, etc.) and so-called table memory devices, e.g. ROM devices (ROM=Read Only Memory)—in particular PROMs, EPROMs, EEPROMs, flash memories, etc.—, and RAM devices (RAM=Random Access Memory or read-write memory), e.g. DRAMs (Dynamic Random Access Memory or dynamic read-write memory) and SRAMs (Static Random Access Memory or static read-write memory).

A RAM device is a memory for storing data under a predetermined address and for reading out the data under this address later. Since it is intended to accommodate as many memory cells as possible in a RAM device, one has been trying to realize same as simple as possible and to scale it as small as possible.

In the case of SRAMs, the individual memory cells consist e.g. of few, for instance 6, transistors, and in the case of so-called DRAMs in general only of one single, correspondingly controlled capacitive element, e.g. a trench capacitor, with the capacitance of which one bit each can be stored as charge.

In the case of such dynamic semiconductor memories, the information or charge, respectively, in the memory cell remains for a relatively short time only. By the diffusion of the charge carriers, the memory contents leave the cell and may flow into the cell environment. Therefore, a so-called “refresh” must be performed regularly, e.g. approximately every 64 ms. In contrast to that, no “refresh” has to be performed in the case of SRAMs since the data stored in the memory cell remain stored as long as an appropriate supply voltage is fed to the SRAM.

In the case of non-volatile memory devices (NVMs), e.g. EPROMs, EEPROMs, and flash memories, the stored data remain, however, stored even when the supply voltage is switched off.

Furthermore, so-called magnetically switching memory devices, e.g. so-called magneto resistive memory devices MRAM (Magnetic Random Access Memory), have recently become known as non-volatile memory devices. The general advantage of the MRAMs vis-a-vis conventional semiconductor memories consists in the permanent storage of the information. Thus, after the switching off and the new switching on of the device in which the memory cells are used, the information stored is available instantly. Therefore, the energy-consuming “refresh” cycles that are required with conventional silicon semiconductor chips may be eliminated.

The functioning of a MRAM provides to store one bit of information each, i.e. a logic “0” or a logic “1”, in a memory cell that consists substantially of two magnetized layers that are adapted to either be magnetized parallel or anti-parallel to each other. In a MRAM memory device, a cell field consisting of a plurality of memory cells and of a matrix of column and row supply lines, or word and bit lines, respectively, is constructed. These supply lines consist of electrically conductive material, wherein the actual MRAM memory cell is positioned at the crosspoints of the supply lines. To achieve a change in the magnetization of an individual memory cell, a magnetic field, the strength of which has to exceed a certain threshold value, is selectively generated in the direct vicinity of a freely addressable crosspoint. The required magnetic field is obtained pursuant to the usual selection mode by the vector addition of the two magnetic fields pertaining to a particular crosspoint and generated by the column and row supply lines.

The column and row supply lines do not only serve to generate magnetic fields for write operations, but they also conduct the read currents for reading out the binary information stored in the individual memory cells. The magnetic memory state of a memory cell is determined by the measurement of a particular physical property, namely the electric resistance, at and through the memory cell itself.

In the case of MRAM memory cells, the utilization of various magneto resistance effects is possible, which are each based on different physical principles. When changing the orientation of magnetization from a parallel to an anti-parallel polarization or vice versa, it is essential that great changes in resistance in the range of some percent are achieved, for instance, by means of the giant magneto resistance effect (GMR), or by means of the tunnel magneto resistance effect (TMR).

MRAM memory cells are ideally designed without any switching elements, i.e. as a pure resistance matrix in which the individual memory cells are designed at the crosspoints between word lines and bit lines. The MRAM memory cells stand out by a relatively simple structure and each consist substantially of a layer of a magnetically hard material with high coercive field strength, an insulating layer of e.g. a tunnel oxide, and a magnetically soft material with low coercive field strength.

As has been explained above, the memory cell field of a MRAM memory according to prior art comprises a plurality of metallic write/read lines, or word and bit lines, respectively, arranged on top of each other in x- and y-direction and thus forming a matrix. The magneto resistive MRAM memory device is positioned between two crossing write/read lines and is conductively connected therewith. Electric signals that are applied to the word lines or bit lines cause, due to the currents flowing through the word lines or bit lines, respectively, magnetic fields that have, if they are strong enough, an influence on the magnetic properties of the MRAM memory cells therebelow. For writing information or a bit, respectively, into a MRAM memory cell that is positioned at a crosspoint of a word line and a bit line, an electric signal is applied to both the bit line and the word line. The current signals each generate magnetic fields that overlap and cause a re-magnetization of the MRAM memory cell.

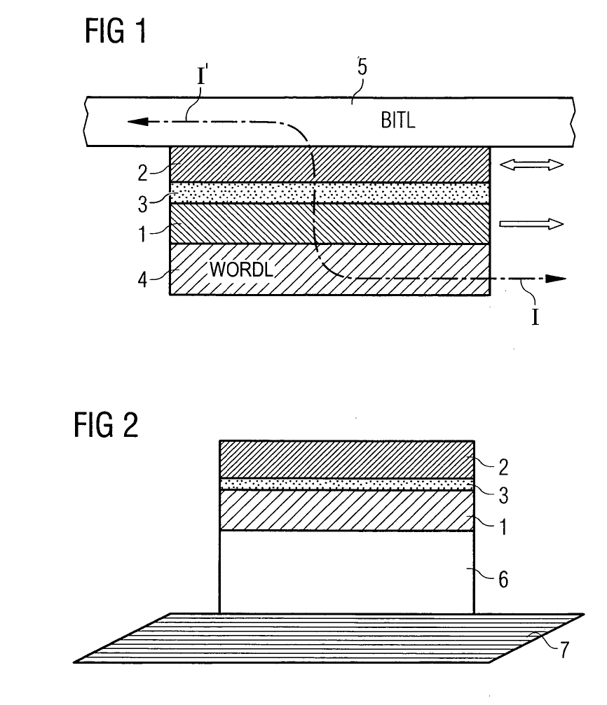

FIG. 1 shows a schematic cross-section of a MRAM memory cell according to prior art, the functioning of which is based on ferromagnetic storage by means of the tunnel magnet resistance (TMR) effect. At the crosspoint between a bit line 5 and a word line 4, there is positioned the TMR memory cell that consists of a layer stack with a magnetically soft layer 2 with a low coercive field strength, a non-magnetic tunnel oxide layer 3, and a magnetically hard reference layer 1 with a high coercive field strength. The two ferromagnetic layers of the memory device comprise, for instance, one of the elements Fe, Ni, Co, Cr, Mn, Gd, or Dy, or combinations of these elements, respectively. The non-magnetic tunnel oxide layer 3 of the MRAM memory cell comprises, for instance, one of the materials Al₂O₃, NiO, HfO₂, TiO₂, NbO, or SiO₂.

The direction of magnetization of the magnetically hard layer 1 indicated by the simple arrow in FIG. 1 is predetermined, while the direction of magnetization of the magnetically soft layer 2 indicated by the double arrow can be adjusted in that appropriate currents I or I′ are conducted through the word line 4 and the bit line 5 in different directions. By means of these currents, the magnetization of the magnetically soft layer 2 may be poled parallel or anti-parallel to the direction of magnetization of the magnetically hard layer 1. In the case of parallel magnetization of the two ferromagnetic layers 1 and 2, the resistance value of the layer stack is lower than in the case of anti-parallel magnetization, which may be evaluated as the state of a logic “0” or a logic “1”, respectively, or vice versa.

The crossing word and bit lines are adapted to be manufactured with minimum dimensions and distances with a minimum structure size, so that a minimum space required per memory cell layer results for each memory device. MRAM memories are therefore adapted to be manufactured with a very high package density. In addition to the high memory density, MRAM memories also stand out vis-a-vis DRAM memories by the fact that the individual memory devices do not require any selection transistor, but are adapted to be directly connected to the word and bit lines. Due to the small size of the MRAM memory devices and of the possible multilayer construction, a plurality of memory devices may be integrated within a very small space in the case of MRAM memories. The magneto resistive memory devices in the memory cell field are controlled by a control logic. The bit lines are connected with a sense amplifier via which the potential at the respective bit line may be regulated to a reference potential, and at which an output signal may be tapped.

It is, however, a problem in the case of such MRAM memory devices that magnetic stray fields from outside the memory or from adjacent memory cells may cause errors in the memory content if they are of sufficient size. Since magnetic fields are difficult to localize, there is, in particular in the case of high package densities and thus closely adjacent supply lines or memory cells, the danger that the magnetic state and thus the memory content of adjacent cells is modified. Another difficulty in the case of a MRAM memory cell consists in that the determination of whether a logic “Zero” or a logic “One” was last stored in the corresponding memory cell may be aggravated after a certain time.

It is therefore an object of the present invention to design a magneto resistive memory (MRAM) of the initially mentioned type such that it is as resistant as possible to magnetic stray fields from outside the memory, i.e. that the information stored in the MRAM memory is as little as possible impaired by external magnetic fields. A further object of the present invention consists in increasing the retention time of the information stored in the MRAM memory. Moreover, it is an object that the magnetic fields for magnetizing the MRAM memory cell are producible with the lowest possible current intensity. Yet another object of the present invention is to provide a method for using MRAM memory devices that fulfils the above-mentioned objects.

These and further objects are solved according to the present invention by the subject matters of claims 1, 12, and 13. Advantageous further developments of the invention are indicated in the subclaims.

In accordance with the invention, the object is achieved with a magneto resistive memory (MRAM) of the initially mentioned kind in that a ferrimagnetic assistant layer is at least partially adjacently positioned at the second magnetizable layer, and is adapted to be magnetically coupled therewith. The present invention thus offers a solution for improving the read out signal and for achieving longer retention of the information or a prolongation of the so-called retention time, respectively, in a MRAM cell.

According to the present invention, a ferrimagnetic assistant layer is applied onto the actual ferromagnetic memory layer of the cell. Ferrimagnetic material has the property of being adapted to be re-magnetized easily at higher temperatures while at lower temperatures it behaves more magnetically hard than ferromagnetic material. Thus, at lower temperatures the ferrimagnetic assistant layer is largely resistant to external magnetic fields. The ferrimagnetic assistant layer is magnetically coupled to the ferromagnetic memory layer. By this magnetic coupling, the magnetization of the ferromagnetic memory layer is “fixed” and thus remains unmodifiable with respect to magnetic stray fields, i.e. the memory layer maintains its magnetization and thus the information stored in the MRAM memory cell without modification. Thus, the stability of the information stored in the ferromagnetic memory layer and hence the retention time of the information stored in the MRAM memory cell is increased, which also improves the reliability during the reading out of the information from the MRAM memory.

During a write process, the corresponding word and bit lines are selected and impacted with a current, which causes a higher temperature to be generated at the corresponding MRAM memory cell. The heat generated by the word and bit lines causes a deactivation of the magnetic coupling between the ferrimagnetic assistant layer and the ferromagnetic memory layer since the ferrimagnetic assistance layer becomes non-magnetic as soon as the temperature range of the Curie temperature (T˜Tcurie)has been reached.

The currents flowing through the word and bit lines further generate a magnetic field that magnetizes the corresponding MRAM memory cell. Both the ferromagnetic memory layer and the ferrimagnetic assistant layer are magnetized. The magnetization of the ferromagnetic memory layer is performed together with that of the ferrimagnetic assistant layer in a particular direction or polarization, respectively, either parallel or anti-parallel to the direction of magnetization or polarization, respectively, of the magnetically hard reference layer as a function of the electric signals or currents applied to the word and bit lines.

During “resting” of the cell, e.g. in the case of a break between a write and a read command, the temperature remains below the Curie temperature (T<Tcurie), and the assistant layer couples magnetically to the memory layer. Since the ferrimagnetic assistant layer at a temperature below the Curie temperature (T<Tcurie) behaves much more magnetically hard than the memory layer, it may not be re-magnetized by external interfering fields or magnetic interactions with neighbor cells. Additionally, the magnetic coupling between the ferrimagnetic assistant layer and the ferromagnetic memory layer prevents differently magnetized partial regions in the memory layer from expanding and from weakening or falsifying, respectively, the information stored.

In the following, the invention will be explained in more detail by means of several embodiments and the enclosed drawing. The drawing shows:

FIG. 1 a schematic representation of a magneto resistive MRAM memory cell according to prior art, which has already been explained;

FIG. 2 a schematic representation of a further magneto resistive MRAM memory cell having a known structure;

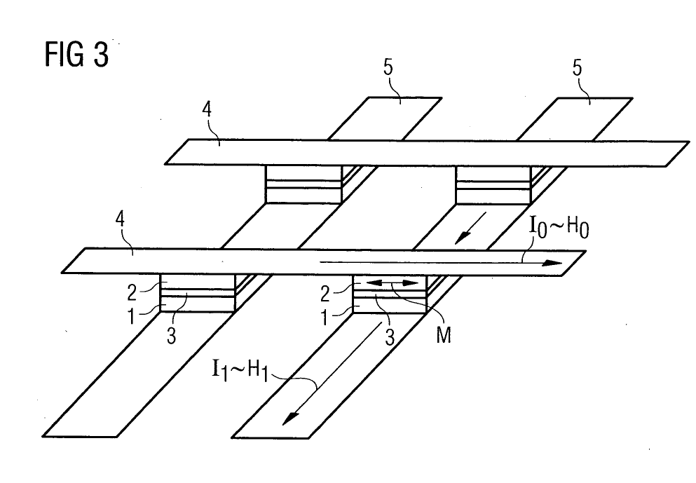

FIG. 3 a schematic representation of the basic structure of magneto resistive MRAM memory cells according to prior art within a matrix of word and bit lines;

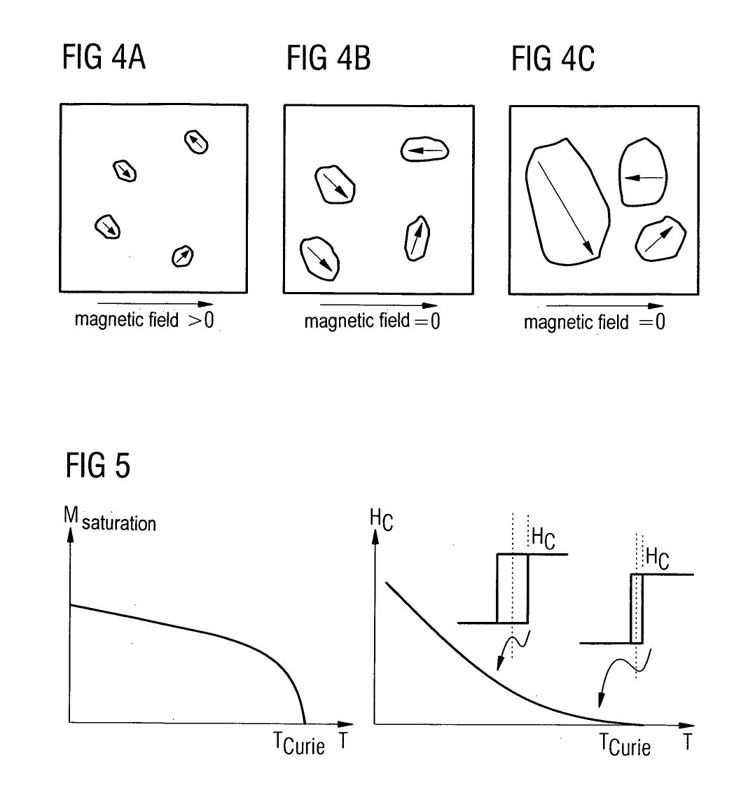

FIG. 4 the time flow of a M-domain movement in a MRAM memory cell according to prior art during a write process; and

FIG. 5 a diagram for illustrating the coercive field strength of a ferrimagnetic assistant layer, and a diagram for illustrating the magnetizing behavior of the ferrimagnetic assistant layer as a function of the temperature.

FIG. 2 shows the schematic representation of a MRAM memory cell with a known structure, consisting of an anti-ferromagnetic layer 6, a non-magnetic or non-magnetizable intermediate layer 3, and two ferromagnetic layers 1 and 2. The first ferromagnetic layer 1 is magnetically hard and strongly coupled to the anti-ferromagnetic layer 6. This layer stack 1, 2, 3 is arranged on a substrate 7. The second ferromagnetic layer 3 has a magnetically soft property and is quasi coupling-free. The first ferromagnetic layer 1 has a constant direction of magnetization and serves as a magnetically hard reference layer. The second ferromagnetic layer 2 is adapted to be modified in its polarization or direction of magnetization, respectively, and serves as the actual memory layer.

While the anti-ferromagnetic layer 6 consists, for instance, of NiO or Fe-NiMn, etc., the non-magnetic or non-magnetizable intermediate layer 3 consists, for instance, of an oxide, CuO, etc., and the two ferromagnetic layers 1 and 2, for instance, of Ni-Fe compounds.

An electric current that flows through the layer stack 2, 3, 1, 6 experiences a differing electric resistance, depending on whether the magnetizations of 1 and 2 are oriented parallel or anti-parallel to each other. The non-magnetic intermediate layer 3 therebetween is responsible for controlling the coupling and the resistance. A signal that is sufficiently high to change the resistance may, for instance, be generated by oxide layers (e.g. AlOx).

FIG. 3 schematically illustrates the basic structure of magneto resistive MRAM memory cells within a matrix defined of word and bit lines 4 and 5. At the respective crosspoints of the word and bit lines 4 and 5, there are positioned MRAM memory cells. Similar to the MRAM memory cell illustrated in FIG. 1, the MRAM memory cells illustrated in FIG. 3 consist of a ferromagnetic memory layer 2, a non-magnetic intermediate layer 3, and a magnetically hard reference layer 1.

The MRAM memory cell is in contact with the word line 4 via the ferromagnetic memory layer 2 and with the bit line 5 via the magnetically hard reference layer 1. During the write process, an electrical (write) current I₀ und I₁ that generates the magnetic fields H₀ und H₁ flows through the thin layer circuit paths of the word and bit lines 4 and 5 in the direction of the arrows. By the overlapping of the two induced magnetic fields H₀ und H₁ at the crosspoint of the word and bit lines 4 and 5, the magnetic state of the MRAM memory cell is modified or impressed, respectively.

By different directions of magnetization or polarization, respectively, of the ferromagnetic memory layer 2, different states of information may be distinguished and stored. The direction of magnetization of the ferromagnetic memory layer 2 may be orientated either parallel or anti-parallel to the direction of magnetization of the magnetically hard reference layer 1, which is indicated by a double arrow in FIG. 3.

After the switching off of the magnetic fields H₀ and H₁, the magnetic state of the MRAM memory cell remains stored, and, depending on the direction of magnetization (M2), a differentiation may be made between a logic “1” and a logic “0”.

For reading out the information stored in the MRAM memory cell, the differing electric resistance of the MRAM memory cell is detected, by means of a (subcritical) current that flows through the same circuit paths 4 and 5 and is lower than the above-mentioned write current, as a function of its state of magnetization. In the case of an anti-parallel orientation of the magnetization between the ferromagnetic memory layer 2 and the magnetically hard reference layer 1, the MRAM memory cell has a high electric resistance that may be assigned to a logic “0”, and in the case of a parallel orientation of the magnetization between the ferromagnetic memory layer 2 and the magnetically hard reference layer 1, the MRAM memory cell has a lower electric resistance that may be assigned to a logic “1”, or vice versa.

As has already been mentioned above, it is of great importance also in the case of a MRAM memory cell that the information stored has a retention time that is as long as possible, without a refresh process having to be performed. In the case of non-volatile memories such as a MRAM, the retention of charge is basically assumed. If, however, one considers a coupling-free magnetic layer such as a Ni-Fe-containing memory layer of a MRAM cell, this layer is magnetized homogeneously in the rarest cases only. Actually, a splitting up of the total magnetization into smaller areas, the so-called magnetic field domains that are not always magnetized parallel to each other, takes place as a rule. The total magnetization of the magnetic layer here results from the vectorial addition of the partial magnetizations in the magnetic layer. The parallelism of the magnetic field domains increases with an increasing magnetic field strength.

A constant polarization of the ferromagnetic memory layer and thus a reliable magnetization of the MRAM memory cell is favored by a larger number of magnetic field domains, so that the establishing of the magnetic field domains in the ferromagnetic memory layer is basically desirable. The establishing of the magnetic field domains may be favored during the production of the magnetic layers. In addition, so-called “pinning centers” that prevent an equidirectional re-magnetization of the M-domains may, for instance, be created by foreign atoms in the ferromagnetic memory layer or by local fluctuations in the material density. Thus, both magnetically hard and magnetically soft magnetic field domains may be created within one magnetic layer.

The walls positioned the different magnetic field domains act like a spring that tries to turn the direction of magnetization of adjacent magnetic field domains in the one or the other direction. This may result in that the magnetic field domains expand or else collapse. Additional external influences such as surrounding magnetic fields, temperature, etc., may have a destructive effect on the stability of the layer magnetization. In the course of time, the total magnetization of such a layer would thus continue decreasing. In the case of a MRAM memory cell, this could, for instance, happen during a long break between a write command (WRITE) and a read command (READ). With respect to the read out signal, this means that the modification of the electric resistance would decrease as strongly as the decrease of the total magnetization in the memory layer of the MRAM memory cell.

In FIG. 4, magnetic field domains are schematically illustrated by bright islands in a coupling-free ferromagnetic magnetic layer, the direction of magnetization of which is indicated by arrows. FIG. 4 illustrates the time flow of the magnetization of a memory layer. In detail, FIG. 4 shows the time flow of the magnetization of a ferromagnetic memory layer or the time flow of a magnetic field domain movement in a MRAM memory cell, respectively, during a write process. FIG. 4A shows the initial state at which an effective magnetic field H₀ and H₁ is induced, which is indicated by the indication “magnetic field>0” below FIG. 4A. In this initial state, the major part of the layer magnetization is oriented substantially parallel to the magnetic field. In the following steps of magnetization, no more magnetic field is induced, which is indicated by the indication “magnetic field=0” below FIGS. 4B and 4C. In the course of time, the partial domains expand, as may be recognized from FIGS. 4B and 4C, this resulting in that the information stored or the read out signal, respectively, is distinctly weakened.

The duration of a magnetic field domain movement depends on the conditions during the production, the base of the growing layer, the temperature, and other factors, and is therefore difficult to determine or strongly dependent on the technology used, respectively. By a higher degree of miniaturization, i.e. a higher storage density, further interfering factors may be created. By the small distance between adjacent memory cells, a so-called crosstalk may also be produced. This effect that is disadvantageous for the stability of the magnetization of the ferromagnetic memory layer is based on the magnetic dipole interaction that increases with decreasing distance and increasing total magnetization.

As a rule, ferromagnetic materials that are very magnetically soft are used for the memory layer, which means that their coercive field strength Hc is very small. The coercive field strength is the field strength that is required for the switching of the magnetization of a layer. This may, indeed, be an advantage since the programmed currents for writing may be kept low, but the information in the coupling-free memory layer 2 may likely be lost for lack of stability due to external influences.

The present invention counteracts the above-described disadvantages in that an additional ferrimagnetic assistant layer is provided that supports the actual memory layer 2 in its object of retaining the information and thus improves the read out signal. The assistant layer consists of a ferrimagnetic material having a plurality of advantageous characteristics with respect to magnetization, temperature behavior, and stability of the magnetization. Ferrimagnetic material has a high coercive field strength, which means that its direction of magnetization is easy to modify at a critical temperature close to the so-called Curie temperature Tcurie (approx. 120° C.) and behaves magnetically soft. Below this Curie temperature it is, however, relatively resistant to modifications of its direction of magnetization by external influences and thus behaves magnetically hard.

Due to the fact that the ferrimagnetic assistant layer and the ferromagnetic memory layer are, pursuant to the invention, magnetically coupled with each other, the ferrimagnetic assistant layer transfers its magnetic properties to the ferromagnetic memory layer and may thus obtain the direction of magnetization of the ferromagnetic memory layer and preserve it better from modifications by external influences. Thus, the retention time, the stability of the information stored, and the reliability of the read out signal also increase. As ferrimagnetic materials for the assistant layer, Gd-Fe layers may, for instance, be used. The layer thickness of the assistant layer ranges preferably between D/2 and D, with D being the layer thickness of the memory layer. The magnitude thus is approx. 10 nm.

As has been described above, the development of heat generated by the current in the word and bit lines is important for the write process in the MRAM memory cell. In FIG. 5, the magnetization behavior is illustrated as a function of the temperature T in the left diagram, and the coercive field strength Hc of the ferrimagnetic assistant layer is illustrated as a function of the temperature in the right diagram. Ferrimagnets have a distinctly lower magnetic moment than ferromagnets. Due to this fact, the magnetic dipole interaction between adjacent memory cells is negligible. In the vicinity of the critical Curie temperature Tcurie at which the magnetic moment disappears, a re-magnetization (writing or overwriting, respectively) of the memory cell is easier to perform. The temperature range close to the Curie temperature Tcurie is therefore also referred to as writing range since a modification of the magnetization of the ferromagnetic memory layer and of the ferrimagnetic assistant layer is possible at this temperature.

As may be seen from the right diagram of FIG. 5, the coercive field strength Hc of a ferrimagnet is very small close to the Curie temperature Tcurie only, while it increases with decreasing temperature T. This means that, with the operating temperature of an inventive MRAM memory cell below the Curie temperature, or during the writing of adjacent cells, respectively, the information stored in the memory cell in the form of a direction of magnetization will remain stable. Moreover, the coercive field strength Hc may be controlled by the chemical composition of the layers at a fixed temperature. The left diagram of FIG. 5 reveals that the magnetization Ms of the ferrimagnetic material decreases with increasing temperature and approaches Zero at the Curie temperature Tcurie. This way, the heat developed during the write process results in that the ferrimagnetic assistant layer of an inventive MRAM memory cell reaches the Curie temperature Tcurie and thus becomes practically non-magnetic. By eliminating the magnetization of the ferrimagnetic assistant layer, the magnetization of the ferromagnetic memory layer may be modified.

The Curie temperature Tcurie may vary according to the composition of the ferrimagnetic material. For the present invention, a ferrimagnetic material with a critical temperature Tcurie of approx. 120° is used. The coercive field strength Hc is very small close to the critical temperature Tcurie and increases with decreasing temperature. The coercive field strength Hc also depends on the composition of the ferrimagnetic material.

The selection of the material hence plays an important role for the function of the ferrimagnetic assistant layer. For the ferrimagnetic assistant layer, materials that have a relatively low critical Curie temperature Tcurie are particularly suited.

At a temperature close to the Curie temperature Tcurie, the ferrimagnetic assistant layer loses its magnetization, and the magnetic coupling to the ferromagnetic memory layer is released. This effect is important for the write process since the ferromagnetic memory layer is adapted to be re-magnetized by the relatively small magnetic fields generated by the low currents in the word and bit lines, without a resistance by coupling effects obstructing the write process.

With decreasing temperature after the termination of the write process, when the MRAM memory cell is no longer selected, the magnetization of the ferrimagnetic assistant layer increases and orients itself towards the ferromagnetic memory layer. This way, the ferrimagnetic assistant layer copies the information from the ferromagnetic memory layer and is magnetically coupled therewith. During the further cooling down, the coercive field strength Hc of the ferrimagnetic assistant layer increases. The ferrimagnetic assistant layer is then much more magnetically hard than the ferromagnetic memory layer.

In order to magnetically turn the coupled layer system according to the present invention in the cooled state below the Curie temperature Tcurie, which would result in the modification of the information of the MRAM memory, much stronger magnetic fields would have to be used than are required with a MRAM memory cell according to prior art. Moreover, the magnetic field domains of the ferromagnetic memory layer described above cannot expand, so that they are themselves coupled to the magnetization of the ferrimagnetic assistant layer. This way, the ferrimagnetic assistant layer ensures the retention of the content of the inventive memory cell and thus also results in a stable read out signal.

### LIST OF REFERENCE SIGNS

1 magnetically hard reference layer
2 ferromagnetic memory layer
3 non-magnetic intermediate layer
4 column or row supply line, or word or bit line, respectively
5 column or row supply line, or word or bit line, respectively
6 anti-ferromagnetic layer
7 substrate

1. A magneto resistive memory comprising a plurality of MRAM memory cells with a first ferromagnetic layer or reference layer, respectively, a second ferromagnetic layer or magnetizable memory layer, respectively, that is adapted to be magnetized by an external magnetic field, and a non-magnetic or non-magnetizable intermediate layer that is positioned between the first and the second ferromagnetic layer, wherein the memory cells are each formed at the crosspoints of a cell field constructed of a matrix of column and row supply lines and are connected to the supply lines for transmitting read and write currents, wherein, during a write operation, the magnetic fields generated in the respective supply lines by the write currents add up in an optional crosspoint and thus enable a magnetization or re-magnetization, respectively, of the corresponding memory cell, wherein
a ferrimagnetic assistant layer is at least partially adjacently positioned at the second magnetizable layer or at the ferromagnetic memory layer (2), respectively, and is adapted to be magnetically coupled therewith.

2. The magneto resistive memory according to claim 1, wherein said ferromagnetic memory layer is adapted to be magnetized in differing directions of magnetization, in particular parallel or anti-parallel to a direction of magnetization of said reference layer.

3. The magneto resistive memory according to claim 1, wherein said ferrimagnetic assistant layer is magnetically coupled with said ferromagnetic memory layer below a particular temperature (Tcurie), so that a magnetization of said ferromagnetic memory layer is maintained.

4. The magneto resistive memory according to claim 1, wherein said ferrimagnetic assistant layer is magnetically decoupled from said ferromagnetic memory layer in the range of and above a particular temperature (Tcurie), so that a magnetization or re-magnetization, respectively, of said ferromagnetic memory layer is possible.

5. The magneto resistive memory according to claim 1, wherein said reference layer is made of a magnetically hard material with high coercive field strength and comprises a particular direction of magnetization.

6. The magneto resistive memory according to claim 1, wherein said ferromagnetic memory layer is made of a magnetically soft material with low coercive field strength.

7. The magneto resistive memory according to claim 1, wherein said ferrimagnetic assistant layer has magnetically hard characteristics below a particular temperature (Tcurie) and maintains its magnetization.

8. The magneto resistive memory according to claim 1, wherein said ferrimagnetic assistant layer has magnetically soft characteristics in the range of and above a particular temperature (Tcurie) and loses its magnetization.

9. The magneto resistive memory according to claim 1, wherein said MRAM memory cells further comprise an anti-ferromagnetic layer that is magnetically coupled with said reference layer.

10. The magneto resistive memory according to claim 1, wherein said MRAM memory cell is positioned on a semiconductor substrate in which a circuit for generating the read and write currents is integrated, and wherein the supply lines are integrated in the circuit path system of the circuit.

11. The magneto resistive memory according to claim 1, wherein said ferrimagnetic assistant layer is made of Gd-Fe layers, and wherein the layer thickness of said ferrimagnetic assistant layer preferably ranges between the half and the total layer thickness of said ferromagnetic memory layer.

12. A method for using a MRAM memory device according to claim 1, said method comprising at least the following steps:
selecting MRAM memory cell to be written
selecting the corresponding supply lines,
impacting the corresponding supply lines with write currents,
generating a temperature above a particular temperature (Tcurie) in the MRAM memory cell at the crosspoint of the corresponding supply lines,
generating magnetic fields by the write currents at the crosspoint of the corresponding supply lines and inducing the magnetic fields in the corresponding MRAM memory cell,
magnetizing the ferromagnetic memory layer and/or the ferrimagnetic assistant layer by overlapping the magnetic fields.

13. A method for using a MRAM memory device according to claim 1, said method comprising at least the following steps:
selecting a MRAM memory cell to be written
selecting the corresponding supply lines,
impacting the corresponding supply lines with read currents,
generating a temperature below a particular temperature (Tcurie) in the MRAM memory cell at the crosspoint of the corresponding supply lines,
measuring the read current flowing through the corresponding MRAM memory cell,
evaluating the read current measured and assigning a logic state of the MRAM memory cell.
